(19) United States
(12) Patent Application Publication
(10) Pub. No.: US 2007/0037358 A1
(43) Pub. Date: Feb. 15, 2007

(54) Apparatus for etching a glass substrate

(75) Inventors: Gi-Won Lee, Suwon-si (KR); Seung-Ju Choi, Ansan-si (KR); Myung-Won Kang, Ansan-si (KR); Kwang-Ju Sung, Ansan-si (KR)

Correspondence Address: HARNESS, DICKEY & PIERCE, P.L.C., P.O. BOX 8910, RESTON, VA, 20195, US

(73) Assignee: Jiwontech Co., Ltd.

(21) Appl. No.: 11/502,411

(22) Filed: Aug. 11, 2006

(30) Foreign Application Priority Data
Aug. 12, 2005 (KR) 2005-74268
Jul. 31, 2006 (KR) 2006-71851

(51) Int. Cl. H01L 21/20

(52) U.S. Cl. 438/381

(57) ABSTRACT

An apparatus for etching a glass substrate includes a container for receiving an etching solution and at least two rollers disposed in the container. The at least two rollers may face with each other. The glass substrate is inserted between the at least two rollers, and the glass substrate is uniformly etched using the etching solution while revolving the at least two rollers.

### CROSS-REFERENCE TO RELATED APPLICATION

This application claims priorities under 35 USC § 119 to Korean Patent Application No. 2005-74268 filed on Aug. 12, 2005 and Korean Patent Application No. 2006-71851 filed on Jul. 31, 2006, the contents of which are incorporated herein by reference in their entirety.

### BACKGROUND OF THE INVENTION

1. Field of the Invention

Embodiments of the present invention relate to an apparatus for etching a glass substrate. More particularly, embodiments of the present invention relate to an apparatus for uniformly etching a glass substrate employed in a flat panel display device.

2. Description of the Related Art

Flat panel devices are generally divided into liquid crystal display (LCD) devices, plasma display panel (PDP) devices, electro luminescent display (ELD) devices, vacuum fluorescent display (VFD) devices, etc. The flat panel device is usually manufactured using a glass substrate of silicon oxide. Since a weight of the glass substrate takes up a big portion in an entire weight of the flat panel display device, it has been significant to decrease the weight of the glass substrate, thereby reducing the entire weight of the flat panel device. For example, the glass substrate is etched or polished to decrease a thickness thereof. Particularly, a thickness of a glass substrate used in the LCD device has been reduced from about 1.2 mm to about 0.8 mm. Additionally, a glass substrate employed in the ELD device has a thin thickness of below about 0.6 mm.

Typically, a glass substrate is immersed in a container in which an etching solution is stored to reduce the thickness thereof by etching it using the etching solution. When etching the glass substrate, the glass substrate needs to be uniformly etched to have an even surface, otherwise an image displayed by the flat panel display device may be considerably deteriorated.

To obtain a glass substrate having a thin thickness and a uniform surface, an etching solution is sprayed or bubbled onto the glass substrate by a spray nozzle or a bubbler after the spray nozzle or the bubbler is installed and the glass substrate is vertically disposed in the container. That is, the glass substrate is etched using the etching solution provided from the spray nozzle or the bubbler. For example, Korean Laid-Open Patent Publication No. 2000-19079 discloses a conventional apparatus for etching a glass substrate by bubbling an etching solution onto the glass substrate. Additionally, Korean Laid-Open Patent Publication No. 1998-1895 discloses a conventional apparatus for etching a glass substrate by spraying an etching solution onto the glass substrate. However, the conventional apparatus for etching the glass substrate may not produce a glass substrate having a uniform surface required for manufacturing a currently demanded flat panel display device

Accordingly, a glass substrate is etched using an etching solution, and then the etched glass substrate is polished to have a uniform surface. Here, the etched glass substrate may be broken while polishing the glass substrate because a relatively high strength is applied to the etched glass substrate.

Meanwhile, a glass substrate is etched using an etching solution including a hydrogen fluoride solution. For example, Korean Laid-Open Patent Publication No. 2000-24808 discloses a method of etching a glass substrate using an etching solution including a hydrogen fluoride solution and deionized water. However, the etching solution including the hydrogen fluoride solution is reacted with the glass substrate so as to generate etched by-products such as hydrosilicofluoric acid. The etched by-products of hydrosilicofluoric acid may be adhered to a surface of the glass substrate, and thereby to deteriorate a uniformity of the surface of the glass substrate. Additionally, the etched by-products of hydrosilicofluoric acid may corrode elements in an etching apparatus such as a spray nozzle when remaining in the etching solution. Furthermore, the etched by-products of hydrosilicofluoric acid are volatile and very poisonous, hence it is necessary to pay special attention when handling the etched by-products of hydrosilicofluoric acid.

### SUMMARY OF THE INVENTION

Embodiments of the present invention provide a method of forming a metal wiring in a semiconductor device without generating a bridge between adjacent metal wirings.

According to one aspect of the present invention, there is provided an apparatus for etching a glass substrate including a container for receiving an etching solution and at least two rollers disposed in the container. The at least two rollers may face with each other. The glass substrate is inserted between the at least two rollers, and the glass substrate is etched using the etching solution while revolving the at least two rollers.

In some embodiments of the present invention, the at least two rollers may include sponge pads, brushes or water-current generating pads having water-current generating members, respectively. The sponge pads or the brushes may contact with the glass substrate. The water-current generating pads having the water-current generating members may be separated from the glass substrate.

In some embodiments of the present invention, the container may include an inner reservoir for storing the etching solution and an outer reservoir for receiving the etching solution overflowed from the inner reservoir. The apparatus may further include a circulation line for circulating the etching solution from the outer reservoir into the inner reservoir, a filter for filtering the etching solution, a buffer tank for storing the etching solution, and a pump for circulating the etching solution.

In some embodiments of the present invention, the apparatus may further include a spray nozzle disposed on a bottom of the container to provide the etching solution onto the glass substrate interposed between the rollers when the rollers are vertically disposed in the container.

In some embodiments of the present invention, the apparatus may further include a spray nozzle disposed on a lateral portion of the container to provide the etching solution onto the glass substrate interposed between the rollers when the rollers are horizontally disposed in the container.

In some embodiments of the present invention, the apparatus may further include a bubbler disposed on a bottom of the container to bubble the etching solution onto the glass substrate interposed between the rollers when the rollers are vertically disposed in the container.

In some embodiments of the present invention, the apparatus may further include a bubbler disposed on a lateral portion of the container to bubble the etching solution onto the glass substrate interposed between the rollers when the rollers are horizontally disposed in the container.

In some embodiments of the present invention, the etching solution may include fluoride salt such as ammonium fluoride, hydrofluoride solution (fluoric acid solution), a mixture thereof, etc.

According to another aspect of the present invention, there is provided an apparatus for etching a glass substrate including a container for receiving an etching solution, a rotating roller disposed in the container, and a water-current generating pad disposed on the roller. The water-current generating pad includes a water-current generating member. The glass substrate immersed in the etching solution is etched by providing an etching solution flow generated by rotating the roller onto the glass substrate while removing etched by-products generated by etching the glass substrate.

In some embodiments of the present invention, the roller having the water-current generating pad may be vertically or horizontally disposed in the container.

In some embodiments of the present invention, the apparatus may further include a first traverse member connected to the roller to enable the roller to move in upward, downward, right and left directions.

In some embodiments of the present invention, the apparatus may further include a second traverse member for holding the glass substrate, thereby enabling the glass substrate to move in upward, downward, right and left directions.

In some embodiments of the present invention, the container may include an inner reservoir for storing the etching solution and an outer reservoir for receiving the etching solution overflowed from the inner reservoir. Here, the apparatus may further include a circulation line for circulating the etching solution from the outer reservoir into the inner reservoir, a filter for filtering the etching solution, a buffer tank for storing the etching solution, and a pump for circulating the etching solution.

According to the present invention, a glass substrate having a thin thickness and a uniform surface may be relatively easily obtained with low cost using an apparatus for etching a glass substrate while ensuring reliability of the glass substrate. Additionally, an etching process for etching the glass substrate may be stably carried out because the glass substrate may be supported by a roller in the etching process. Particularly, the glass substrate may be more uniformly etched using the apparatus including a water-current generating pad that generates strong flow of an etching solution. Furthermore, the etching solution including fluoride salt may effectively etch the glass substrate by reducing etched by-products.

### BRIEF DESCRIPTION OF THE DRAWINGS

The above and other features and advantages of the present invention will become readily apparent by reference to the following detailed description when considered in conjunction with the accompanying drawings wherein:

FIG. 1 is a cross-sectional view illustrating an apparatus for etching a glass substrate in accordance with example embodiments of the present invention;

FIGS. 2 to 4 are perspective views illustrating pads disposed on rollers in accordance with example embodiments of the present invention;

FIG. 5 is a cross-sectional view illustrating an apparatus for etching a glass substrate in accordance with example embodiments of the present invention;

FIG. 6 is a picture showing a first sample solution and a second sample solution;

FIG. 7A is a picture showing etched by-products obtained from the first sample solution;

FIG. 7B is a picture showing etched by-products obtained from the second sample solution; and

FIGS. 8 to 13 are graphs showing surface uniformities of glass substrates.

### DESCRIPTION OF THE EMBODIMENTS

The present invention is described more fully hereinafter with reference to the accompanying drawings, in which example embodiments of the present invention are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-sectional illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

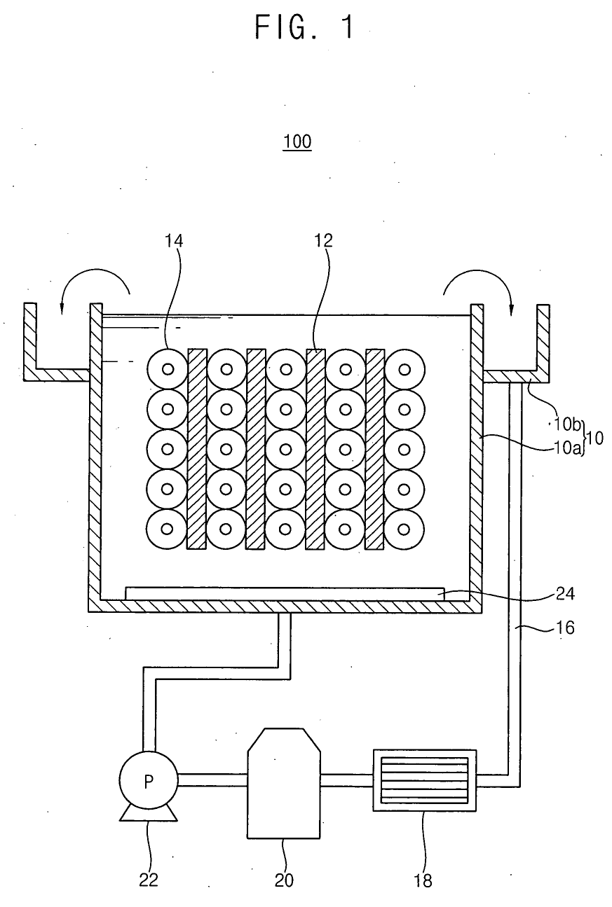

FIG. 1 is a cross-sectional view illustrating an apparatus for etching a glass substrate in accordance with example embodiments of the present invention.

Referring to FIG. 1, a glass substrate etching apparatus 100 includes a container 10 that receives an etching solution for etching a glass substrate 12. The glass substrate 12 may include silicon oxide suitably employed in a flat panel display device.

In some embodiments of the present invention, the apparatus 100 may overflow the etching solution onto the glass substrate 12 so as to properly circulate the etching solution around the glass substrate 12.

The container 10 includes an inner reservoir 10a and an outer reservoir 10b. The inner reservoir 10a receives the etching solution and the outer reservoir 10b encloses an upper portion of the inner reservoir 10a. The outer reservoir 10b receives the etching solution overflowed from the inner reservoir 10a.

The apparatus 100 further includes at least two rollers 14 disposed in the container 10. The included at least two rollers 14 may face with each other by a predetermined interval. The glass substrate 12 may be inserted between the included rollers 14. In some embodiments of the present invention, two series of rollers 14 are continuously disposed by interposing the glass substrate 12 between the two series of the rollers 14. Particularly, a roller unit including several series of the rollers 14 may be disposed in the container 12 so as to simultaneously etch a plurality of glass substrates 12.

In an etching process for etching the glass substrates 12 using the apparatus 100, the glass substrates 12 are inserted among the rollers 14, respectively. The glass substrates 12 inserted among the rollers 14 may be etched using the etching solution while revolving the rollers 14.

In some embodiments of the present invention, the etching solution may make uniform contact with the glass substrates 12 because the rollers 14 rotate when the glass substrates 12 are etched. Additionally, etched by-products generated in the etching process may not be adhered to the glass substrates 12 in accordance with the rotation of the rollers 14. As a result, the glass substrates 12 may have uniform surfaces due to the rotating rollers 14 and the uniformly provided etching solution.

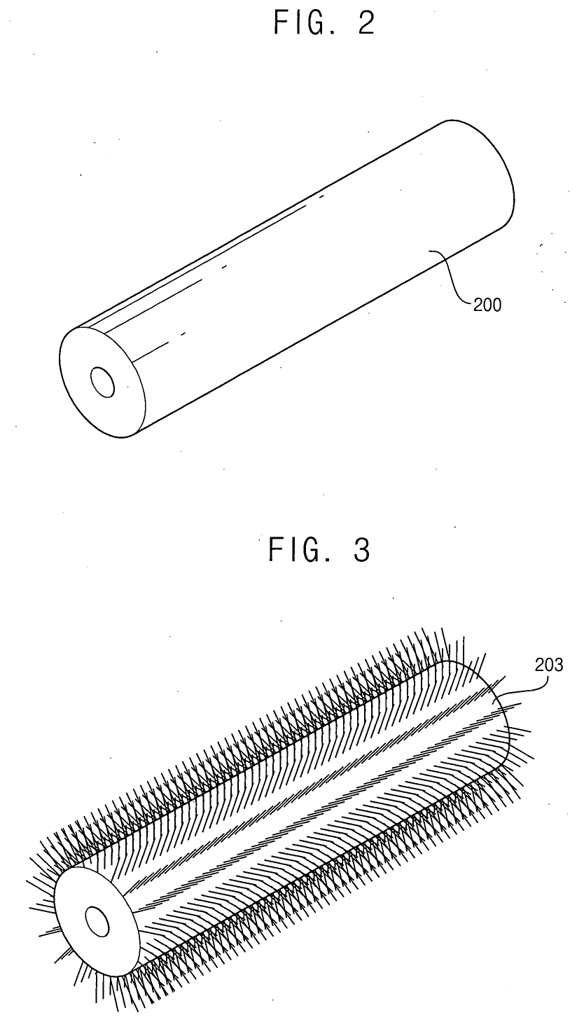

FIGS. 2 to 4 are perspective views illustrating pads disposed on rollers in accordance with example embodiments of the present invention.

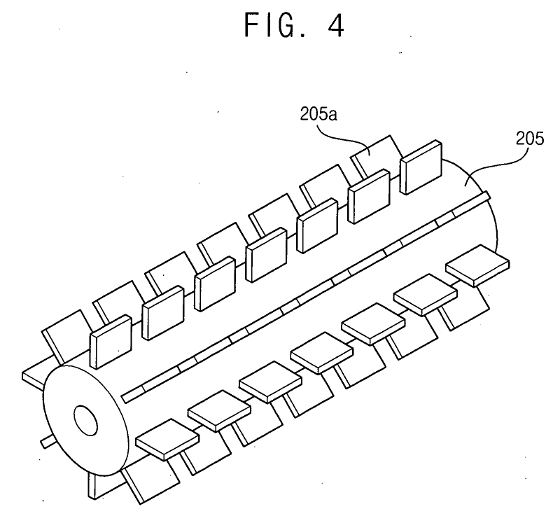

Referring to FIGS. 2 to 4, the apparatus 100 may include various pads disposed on the rollers 14, respectively. Each of the pads may effectively reduce impact applied to the glass substrates 12 during the etching process. In one example embodiment of the present invention, the apparatus 100 may include a sponge pad 200 disposed on the roller 14 as shown in FIG. 2. In another example embodiment of the present invention, the apparatus 100 may include a brush 203 formed on the roller 14 as shown in FIG. 3. In still another example embodiment of the present invention, the apparatus 100 may include a water-current generating pad 205 disposed on the roller 14 as shown in FIG. 4. The water-current generating pad 205 includes a water-current generating member 205a.

When the apparatus 100 includes the sponge pad 200 or the brush 203 disposed on the roller 14, the sponge pad 200 or the brush 203 may directly contact with the glass substrate 12. The sponge pad 200 or the brush 203 may not tightly press the glass substrate 12, and thereby to avoid damages to the glass substrate 12 when the sponge pad 200 or the brush 203 makes direct contact with the glass substrate 12.

When the apparatus 100 includes the water-current generating pad 205 having the water-current generating member 205a disposed on the roller 14, the water-current generating pad 205 may not make direct contact with the glass substrate 12 because there are risks that the water-current generating member 205a may damage the glass substrate 12. Thus, the water-current generating pad 205 may be separated from the glass substrate 12 by a predetermined interval so that the water-current generating member 205a may generate the strong current of the etching solution to uniformly provide the etching solution onto the glass substrate 12 during the etching process. Additionally, the etched by-products may be effectively removed from the glass substrate 12 by the strong current of the etching solution.

The rollers 14 of the apparatus 100 may stably support the glass substrate 12 inserted between the rollers 14 such that the glass substrate 12 may not be bent or broken in the etching process. Accordingly, the glass substrate 12 having a thin thickness may be sufficiently etched using the apparatus 100 having the rollers 14.

The apparatus 100 further includes a circulation line 16 for circulating the etching solution from the outer reservoir 10b into the inner reservoir 10a of the container 10. Hence, the etching solution may be recycled through the circulation line 16 to reduce the cost of manufacturing the glass substrate 12.

When the apparatus 100 includes the circulation line 16, a filter 18, a buffer tank 20 and a pump 22 are installed along the circulation line 16. Here, the filter 18 filters the etching solution flowing into the circulation line 16 and the buffer tank 20 stores the etching solution to adjust the flow of the etching solution circulating in the circulation line 16. Additionally, the pump 22 effectively circulates the etching solution from the outer reservoir 10b to the inner reservoir 10a.

In some example embodiments of the present invention, the etched by-products in the etching solution may be removed by the filter 18 while circulating the etching solution in the circulation line 16. Here, the buffer tank 20 may properly control the flow rate of the etching solution in the etching process, and the pump 22 may efficiently provide the etching solution onto the glass substrate 12 in the etching process.

In an example embodiment of the present invention, the filter 18, the buffer tank 20 and the pump 22 may be disposed in a serial form based on the flow of the circulation line 16.

The apparatus 100 additionally includes a spray nozzle 24 disposed in the inner reservoir 10a of the container 10. The spray nozzle 24 may uniformly spray the etching solution onto the glass substrate 12 during the etching process.

In some example embodiments of the present invention, the etching solution may include fluoride salt. When the etching solution includes the fluoride salt, the etching solution may be more conveniently used in comparison with an etching solution including a hydrogen fluoride solution. Particularly, the etching solution including the fluoride salt may sufficiently reduce the etched by-products and the corrosion of the spray nozzle 24 in the etching process. Accordingly, the maintenance cost for the apparatus 100 may be considerably reduced when the etching solution including the fluoride slat is used in the etching process.

When the glass substrate 12 includes silicon oxide, the glass substrate 12 may be etched using the etching solution including the hydrogen fluoride (HF) solution as shown in the following chemical reactions (1) and (2):
4HF+SiO₂=SiF₄(gas)+2H₂O₂ (1)
2HF+SiF₄=H₂SiF₆(precipitate) (2)

In some example embodiments of the present invention, the glass substrate 12 including silicon oxide may be etched using the etching solution including the fluoride salt such as NH₄HF₂ in accordance with the following chemical reaction (3):
2NH₄HF₂+SiO₂+H₂O=(NH₄)₂SiF₆(precipitate)+NH₄OH+2H₂O (3)
In the chemical reactions (2) and (3), the precipitates of H₂SiF₆ and (NH₄)₂SiF₆ correspond to the etched by-products generated by etching the glass substrate 12.

As shown in the chemical reactions (1), (2) and (3), the precipitate of (NH₄)₂SiF₆ formed by the etching solution including NH₄HF₂ is substantially different from the precipitate of H₂SiF₆ generated by the etching solution including HF.

Since the precipitate of H₂SiF₆ is glutinous, the etched by-products including H₂SiF₆ may be relatively easily adhered to the glass substrate 12 and/or the elements of the apparatus 100. Additionally, the precipitate of H₂SiF₆ is easily hardened as time goes by, so that the etched by-products including H₂SiF₆ may not be removed from the glass substrate 12 and/or the elements of the apparatus 100. However, the precipitate of (NH₄)₂SiF₆ has an adhesion strength considerably lower than that of the precipitate of H₂SiF₆, so that the etched by-products including (NH₄)₂SiF₆ may be relatively Easily removed from the glass substrate 12 and/or the elements of the apparatus 100. Further, the etched by-products including (NH₄)₂SiF₆ may be more easily removed from the glass substrate 12 and/or the elements of the apparatus 100 because the precipitate of (NH₄)₂SiF₆ is not hardened with passage of time.

When the etching solution includes the fluoride salt, the durability of the spray nozzle 24 may be improved. Additionally, a bubbler may be advantageously employed in the apparatus 100 instead of the spray nozzle 24.

In some example embodiments of the present invention, the rollers 14 may be vertically disposed in the inner reservoir 10a of the container 10. Thus, the spray nozzle 24 may be horizontally disposed on a bottom of the inner reservoir 10a of the container 10. Alternatively, the bubbler may be horizontally installed on the bottom of the inner reservoir 10.

In some example embodiments of the present invention, the rollers 14 may be horizontally disposed in the inner reservoir 10a of the container 10. Alternatively, the bubbler may be disposed on a lateral portion of the inner reservoir 10a.

As described above, the apparatus for etching a glass substrate may uniformly etch at least one glass substrate even though the glass substrate may have a thin thickness, thereby obtaining the glass substrate with a uniform surface.

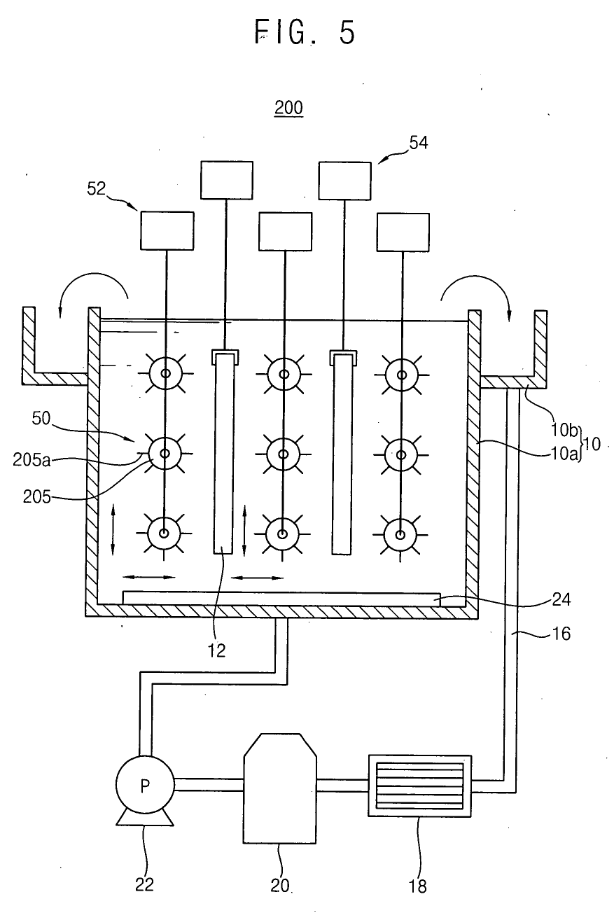

FIG. 5 is a cross-sectional view illustrating an apparatus for etching a glass substrate in accordance with example embodiments of the present invention.

Referring to FIG. 5, a glass substrate etching apparatus 200 includes a container 10 for receiving an etching solution and at least one roller 50 disposed in the container 10. The container 10 includes an inner reservoir 10a and an outer reservoir 10b. The roller 50 is positioned in the inner reservoir 10a. The roller 50 includes a water-current generating pad 205 having a water-current generating member 205a.

When the roller 50 rotates in the inner reservoir 10a receiving the etching solution, the current of the etching solution may be generated by the water-current generating member 205a so as to uniformly provide the etching solution onto a glass substrate 12.

In some example embodiments of the present invention, the roller 50 may be horizontally disposed in the inner reservoir 10a of the container 10. Alternatively, the roller 50 may be vertically installed in the inner reservoir 10a.

In one example embodiment of the present invention, one roller 50 may be installed in the inner reservoir 10a. In another example embodiment of the present invention, a plurality of rollers 50 may be disposed in the inner reservoir 10a. Here, the number of the rollers 50 may be properly adjusted in accordance with the size of the glass substrate 12 to be etched.

When the apparatus 200 etches a plurality of glass substrates 12 at a time, the rollers 50 may face with each other around the glass substrates 12. As described above, the rollers 50 may be spaced apart from the glass substrates 50 by predetermined intervals because the rollers 50 have the water-current generating pads 205, respectively. That is, the water-current generating members 205a of the water-current generating pad 205 may not directly contact with the glass substrates 12. Therefore, the rollers 50 having the water-current generating pads 205 may generate the strong flow of the etching solution to uniformly provide the etching solution onto the glass substrates 12 without damaging the glass substrates 12.

The apparatus 200 further includes at least one first traverse member 52 to enable the rollers 50 to move in upward, downward, right and/or left directions. When the glass substrates 12 are etched in the inner reservoir 10a using the etching solution, the first traverse member 52 moves the glass substrates 12 along the four directions such that the etching solution may be uniformly provided onto the glass substrates 12 in an etching process.

The apparatus 200 additionally includes at least one second traverse member 54 for holding the glass substrates 12 and moving upward, downward, right and/or left. The second traverse member 54 drifts the glass substrates 12 in the four directions so that the etching solution may be more uniformly provided onto the glass substrates 12 in the etching process.

When the rollers 50 having the water-current generating pads 205 are horizontally disposed in the container 10, the first traverse member 52 may move the rollers 50 in upward and downward directions. On the contrary, the first traverse member 52 may transfer the rollers 50 to the right and to the left when the rollers 50 are vertically disposed in the container 10. The second traverse member 54 may move the rollers 50 having the water-current generating pads 205 upwardly and downwardly when the rollers 50 are horizontally installed in the inner reservoir 10a of the container 10. Meanwhile, the second traverse member 54 may move the rollers 50 having the water-current generating pads 205 to the right and to the left when the rollers 50 are vertically disposed in the inner reservoir 10a of the container 10.

As described above, the etching solution may be uniformly provided onto the glass substrates 12 by moving the first and the second traverse members 52 and 54.

In some example embodiments of the present invention, the movements of the rollers 50 and the glass substrates 12 by the first and the second traverse members 52 and 54 may vary according to the construction of the apparatus 200.

In some example embodiments of the present invention, the etching solution may include fluoride salt. Hence, the glass substrates 12 may be uniformly etched using the etching solution including the fluoride salt without generating etched by-products on the glass substrates 12 while moving the rollers 50 and the glass substrates 12 using the first and the second traverse members 52 and 54. As a result, the glass substrate 12 having a thin thickness may be obtained using the apparatus 200 having the above-described construction.

Evaluation of Etched By-Products Amount Relative to Etching Solution

To evaluate an amount of etched by-products, a first etching solution including fluoride salt was prepared. After a silicon oxide substrate was etched using the first etching solution, a first sample solution including the first etching solution of about 200 ml and silicon oxide of about 5 g was obtained. Meanwhile, a second etching solution including about 18 volume percent of a hydrogen fluoride solution was prepared. A silicon oxides substrate was etched using the second etching solution, and then a second sample solution including the second etching solution of about 200 ml and silicon oxide of about 5 g was obtained. The first and the second sample solutions were kept in an air for about two hours.

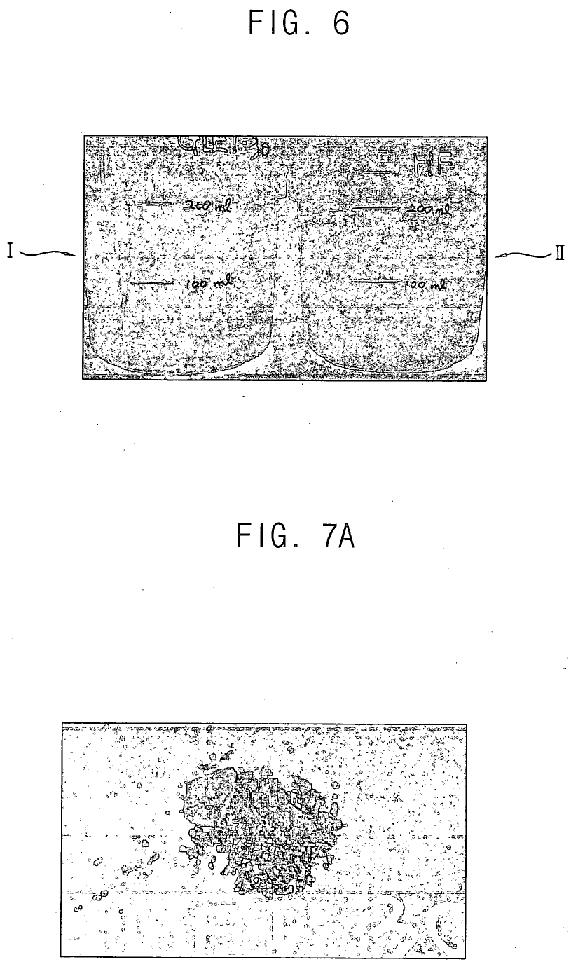

FIG. 6 is a picture showing the first sample solution (I) and the second sample solution (II).

As shown in FIG. 6, an amount of the etched by-products in the first sample solution (I) was about 50 ml, whereas an amount of the etched by-products in the second sample solution (II) was about 150 ml. The first etching solution including the fluoride salt may reduce the amount of the etched by-products comparing to the second etching solution including the hydrogen fluoride solution. Since the amount of the etched by-products may decrease when the silicon oxide substrate is etched using the first etching solution including the fluoride salt, the etched by-products may be relatively easily removed from the substrate and/or elements of an apparatus while etching a glass substrate.

Evaluation of Conditions of Etched By-Products

To evaluate conditions of the etched by-products, the first and the second sample solutions were filtered using filer papers, respectively, thereby obtaining the etched by-products. The etched by-products were dried in an air for about 24 hours.

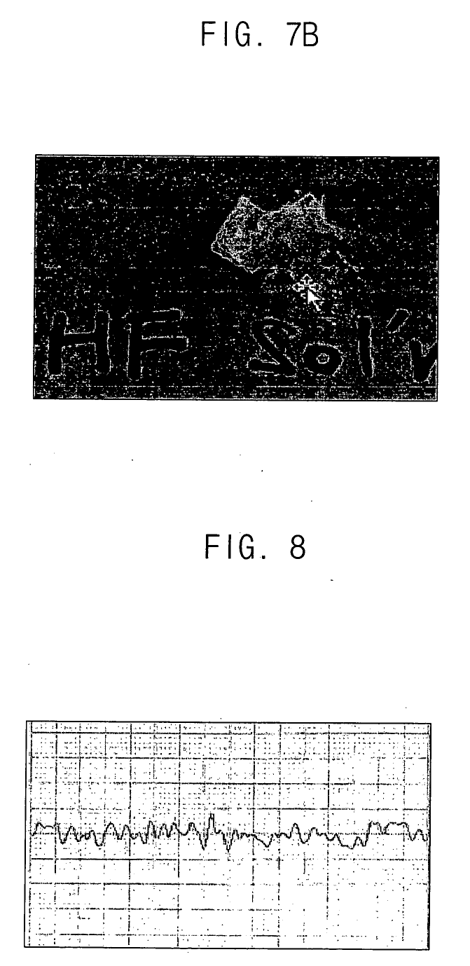

FIG. 7A is a picture showing the etched by-products obtained from the first sample solution, and FIG. 7B is a picture showing the etched by-products obtained from the second sample solution.

As shown in FIGS. 7A and 7B, the etched by-products obtained from the first sample solution are in a powder state, whereas the etched by-products obtained from the second sample solution are in a bulk state. Since the etched by-products obtained from the first sample solution including the fluoride salt are in a powder state, the etched by-products obtained from the first sample solution may be easily removed from the glass substrate and/or the elements of the apparatus. Therefore, the glass substrate may be effectively etched using an etching solution including fluoride salt comparing to an etching solution including a hydrogen fluoride solution.

Evaluation of Uniformity of Glass Substrates

FIGS. 8 to 13 are graphs showing surface uniformities of glass substrates. In FIGS. 8 to 13, vertical axes represent root-mean-square (RMS) of the glass substrates and horizontal axes indicate widths of the glass substrates.

After a raw glass substrate was prepared, a surface uniformity, i.e., a surface roughness (RMS) of the raw glass substrate was measured. The mean roughness of the surface of the raw material is about 0.01 μm as shown in FIG. 8.

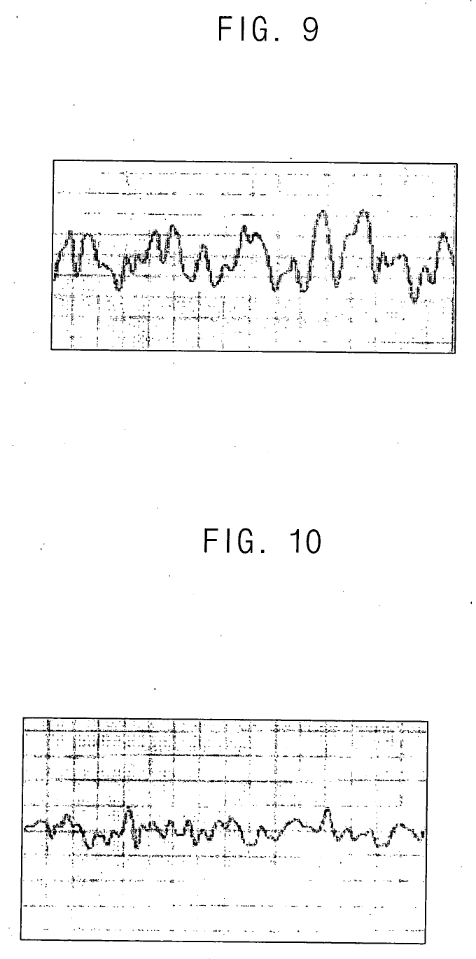

A first glass substrate was etched using an apparatus having a bubbler after the first glass substrate was immersed in a first etching solution including about 18 volume percent of a hydrogen fluoride solution for about 30 minutes. A surface uniformity of the first glass substrate was measured. As shown in FIG. 9, a mean roughness of the surface of the first glass substrate is about 0.04 μm.

A second glass substrate was etched using an apparatus having a bubbler after the second glass substrate was immersed in a second etching solution including fluoride salt for about 30 minutes. A surface uniformity of the second glass substrate was measured. A mean roughness of the surface of the second glass substrate is about 0.01 μm as shown in FIG. 10.

A third glass substrate was etched using an apparatus having a sponge pad after the third glass substrate was immersed in a third etching solution including fluoride salt for about 30 minutes. A surface uniformity of the third glass substrate was measured. A mean roughness of the surface of the third glass substrate is about 0.01 μm as shown in FIG. 11.

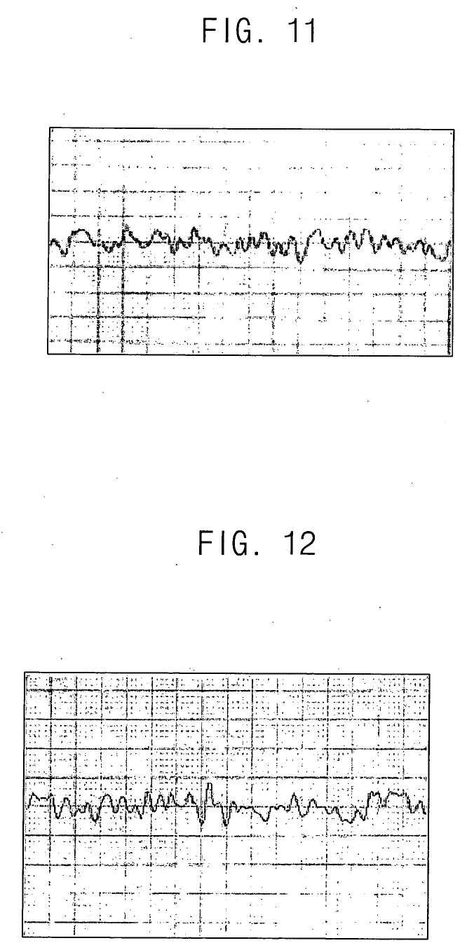

A fourth glass substrate was etched using an apparatus having a brush after the fourth glass substrate was immersed in a fourth etching solution including fluoride salt for about 30 minutes. A surface uniformity of the fourth glass substrate was measured. As shown in FIG. 12, a mean roughness of the surface of the fourth glass substrate is about 0.01 μm.

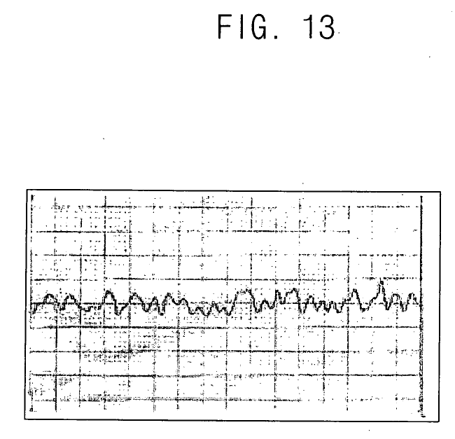

A fifth glass substrate was etched using an apparatus having a water-current generating pad after the fifth glass substrate was immersed in a fifth etching solution including fluoride salt for about 30 minutes. A surface uniformity of the fifth glass substrate was measured. As shown in FIG. 13, a mean roughness of the surface of the fifth glass substrate is about 0.01 μm.

As described above, an etching solution including fluoride salt may uniformly etch a glass substrate such that the glass substrate may have a uniform surface and a thin thickness.

According to the present invention, a glass substrate having a thin thickness and a uniform surface may be easily obtained with a low cost using an apparatus for etching a glass substrate while ensuring a reliability of the glass substrate. Additionally, an etching process for etching the glass substrate may be stably carried out because the glass substrate may be supported by a roller in the etching process. Particularly, the glass substrate may be more uniformly etched using the apparatus including a water-current generating pad that generates strong flow of an etching solution. Furthermore, the etching solution including fluoride salt may effectively etch the glass substrate by reducing etched by-products.

The foregoing is illustrative of the present invention and is not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. An apparatus for etching a glass substrate comprising:
a container for receiving an etching solution; and
at least two rollers disposed in the container, the at least two rollers facing with each other,
wherein the glass substrate is inserted between the at least two rollers, and the glass substrate is etched using the etching solution while revolving the at least two rollers.

2. The apparatus of claim 1, wherein the at least two rollers comprise sponge pads, brushes or water-current generating pads having water-current generating members, respectively.

3. The apparatus of claim 2, wherein the sponge pads or the brushes make contact with the glass substrate.

4. The apparatus of claim 2, wherein the water-current generating pads having the water-current generating members are separated from the glass substrate.

5. The apparatus of claim 1, wherein the container comprises an inner reservoir for storing the etching solution and an outer reservoir for receiving the etching solution overflowed from the inner reservoir.

6. The apparatus of claim 6, further comprising:
a circulation line for circulating the etching solution from the outer reservoir into the inner reservoir;
a filter for filtering the etching solution;
a buffer tank for storing the etching solution; and
a pump for circulating the etching solution.

7. The apparatus of claim 1, further comprising a spray nozzle disposed on a bottom of the container to provide the etching solution onto the glass substrate interposed between the rollers when the rollers are vertically disposed in the container.

8. The apparatus of claim 1, further comprising a spray nozzle disposed on a lateral portion of the container to provide the etching solution onto the glass substrate interposed between the rollers when the rollers are horizontally disposed in the container.

9. The apparatus of claim 1, further comprising a bubbler disposed on a bottom of the container to bubble the etching solution onto the glass substrate interposed between the rollers when the rollers are vertically disposed in the container.

10. The apparatus of claim 1, further comprising a bubbler disposed on a lateral portion of the container to bubble the etching solution onto the glass substrate interposed between the rollers when the rollers are horizontally disposed in the container.

11. The apparatus of claim 1, wherein the etching solution comprises fluoride salt, hydrofluoride solution or a mixture thereof.

12. An apparatus for etching a glass substrate comprising:
a container for receiving an etching solution;
a rotating roller disposed in the container; and
a water-current generating pad disposed on the roller, the water-current generating pad including a water-current generating member,
wherein the glass substrate immersed in the etching solution is etched by providing a flow of the etching solution generated by a rotation of the roller onto the glass substrate while removing etched by-products generated in etching the glass substrate.

13. The apparatus of claim 12, wherein the roller having the water-current generating pad is vertically or horizontally disposed in the container.

14. The apparatus of claim 12, further comprising a first traverse member connected to the roller to move the roller in upward, downward, right and left directions.

15. The apparatus of claim 12, further comprising a second traverse member for holding the glass substrate to move the glass substrate in upward, downward, right and left directions.

16. The apparatus of claim 12, wherein the container comprises an inner reservoir for storing the etching solution and an outer reservoir for receiving the etching solution overflowed from the inner reservoir.

17. The apparatus of claim 18, further comprising:
a circulation line for circulating the etching solution from the outer reservoir into the inner reservoir;
a filter for filtering the etching solution;
a buffer tank for storing the etching solution; and
a pump for circulating the etching solution.

18. The apparatus of claim 12, wherein the etching solution comprises fluoride salt hydrofluoride solution or a mixture thereof.
